(19) United States
(12) Patent Application Publication
(10) Pub. No.: US 2009/0095864 A1
(43) Pub. Date: Apr. 16, 2009

(54) RETAINING STRUCTURE FOR HOLDING ELECTRONIC DEVICE IN POINT OF SALE SYSTEM TERMINAL

(75) Inventors: Chien-Ta LIN, Taichung City (TW); Kuo-Kuang Liu, Nantou County (TW); Ying -Ti Chen, Taichung City (TW)

Correspondence Address: BROWDY AND NEIMARK, P.L.L.C.;624 NINTH STREET, NW, SUITE 300, WASHINGTON, DC, 20001-5303, US

(73) Assignee: Universal Scientific Industrial Co., Ltd., Nan Tou (TW)

(21) Appl. No.: 12/019,828

(22) Filed: Jan. 25, 2008

(30) Foreign Application Priority Data
Oct. 15, 2007 (TW) 96217235

(51) Int. Cl. A47F 5/00; H05K 5/00

(52) U.S. Cl. 248/309.1

(57) ABSTRACT

A retaining structure for holding one or more electronic devices inside a point of sale system terminal includes a support housing having a back plate, two side plates connected with two opposite sides of the back plate, at least two first positioning portions formed on the back plate, and a support plate mounted on the back plate and having at least one protrusion, and a retaining member having at least two second positioning portions detachably coupled to the first positioning portions of the support housing, and at least one groove engaged with the protrusion of the support plate for holding the electronic device between the support housing and the retaining member without using any tool.

### BACKGROUND OF THE INVENTION

1. Field of the Invention

The present invention relates generally to a terminal used in the point of sale system, and more specifically to a retaining structure for a point of sale system terminal, which can be used to hold one or more electronic devices inside the terminal of the point of sale system.

2. Description of the Related Art

Point of sale (hereinafter referred to as “POS”) systems are widely in stores, supermarkets, restaurants, and hotels, as well as almost any type of retail establishment. By means of registering, computerizing and transmitting the information of the products and/or services that have been sold and/or provided through the computer-based terminals of the POS system, reliable and real-time cash, logistics and information flows can be provided for accounting, service management, customer relation management, inventory management, open to buy forecasting, and etc.

The computer-based terminal of POS system is usually equipped with many electronic devices including internal devices and peripheral devices inside the case thereof. For example, an adapter for use in the computer-based terminal of the POS system is conventionally held inside the case of the terminal by a retaining member screwingly connected to the terminal case. If the adapter needs to be repaired or replaced, a user has to use a screwdriver to remove screws one by one for disassembling the retaining member from the case of the POS system terminal. In other words, a screwdriver and screws will be needed in order to hold an electronic device inside the terminal case by the conventional retaining member. This is inconvenient in assembly.

### SUMMARY OF THE INVENTION

The present invention has been accomplished in view of the above-noted circumstances. It is one objective of the present invention to provide a retaining structure capable of holding one or more electronic devices in a point of sale system terminal without using any tool, having the advantage of convenience in assembly.

To achieve this objective of the present invention, the retaining structure comprises a support housing and a retaining member detachably coupled to the support housing for holding one or more electronic devices therebetween without using any tool. The support housing includes a back plate and two side plates connected with two opposite sides of the back plate, at least two first positioning portions formed on the back plate, and a support plate mounted on the back plate with at least one protrusion. The retaining member has at least two second positioning portions detachably coupled to the first positioning portions of the support housing, and a groove engaged with the protrusion of the support plate for holding the electronic device between the retaining member and the support housing.

As long as the second positioning portions of the retaining member are disengaged from the first positioning portions of the support housing and the groove is disengaged from the protrusion of the support plate, the retaining member can be disassembled from the support housing without using any tool, thereby enhancing the convenience of repair of the electronic device.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is an exploded view of the retaining structure according to a preferred embodiment of the present invention;

FIG. 2 is a perspective bottom view of the retaining structure in an assembly manner according to the preferred embodiment of the present invention;

FIG. 3 is a front view of the retaining member of the retaining structure according to the preferred embodiment of the present invention;

FIG. 4 is a right side view of the retaining member of the retaining structure according to the preferred embodiment of the present invention;

FIG. 5 is a bottom view of the retaining member of the retaining structure according to the preferred embodiment of the present invention;

FIG. 6 is a perspective view of the retaining structure according to the preferred embodiment of the present invention, showing that the electronic devices are held between the support housing and the retaining member;

FIG. 7 is a rear view of FIG. 6, and

FIG. 8 is a bottom view of FIG. 6.

### DETAILED DESCRIPTION OF THE INVENTION

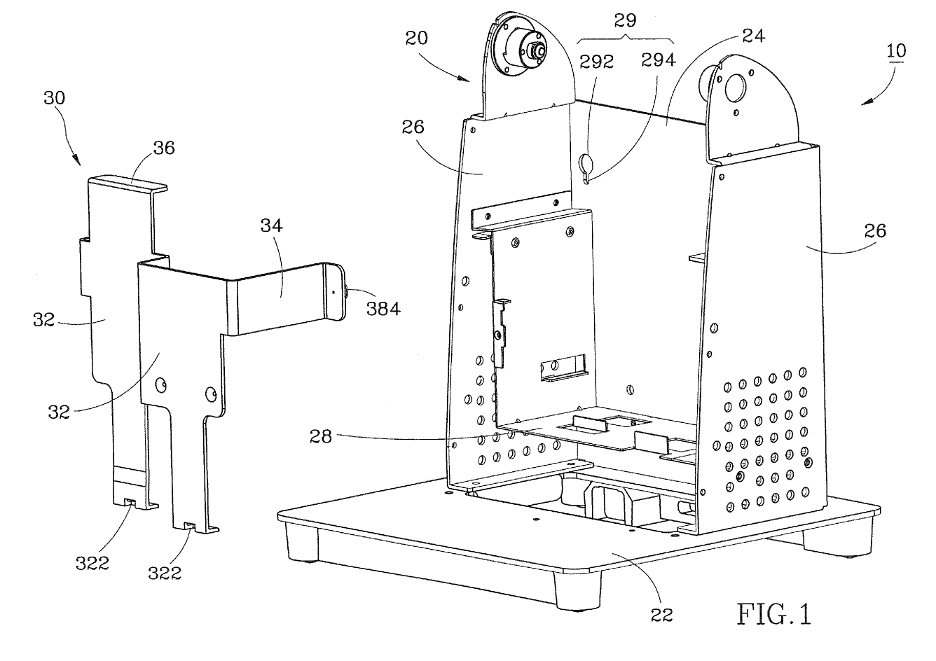

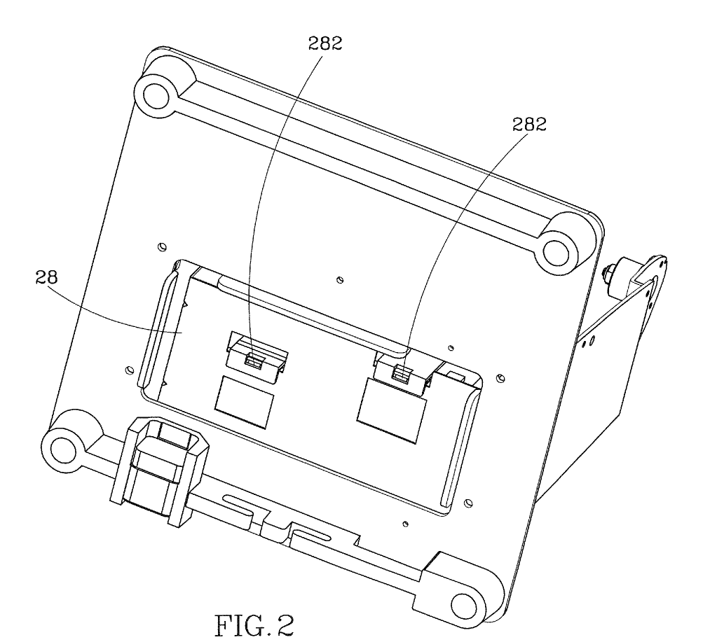

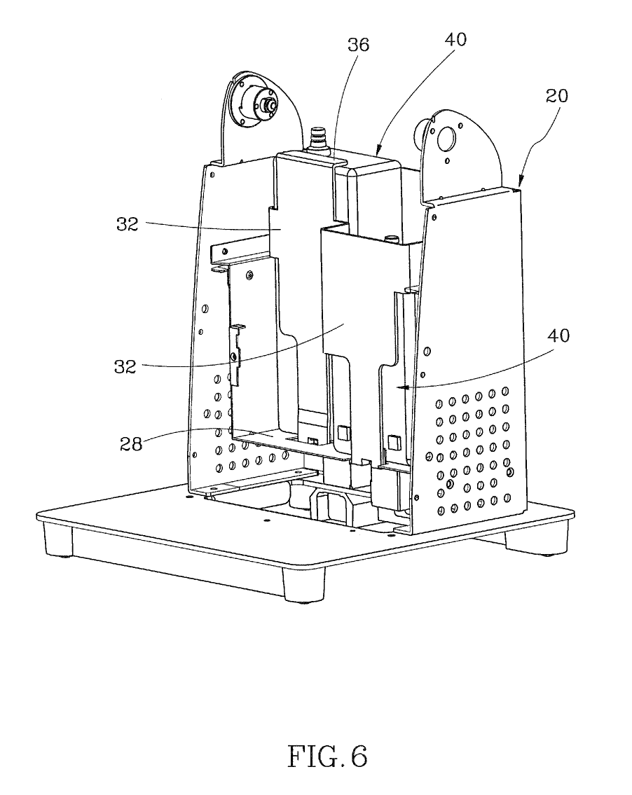

As shown in FIGS. 1 and 2, a retaining structure 10 in accordance with a preferred embodiment of the present invention comprises a support housing 20 and a retaining member 30. The retaining structure 10 is adapted to hold one or more electronic devices, such as, but not limited to, the adapters 40 shown in FIG. 6, inside a POS system terminal (not shown). As will be however appreciated, the support housing 20 may be a part of the case (not shown) of the POS system terminal or an individual element mounted inside the terminal case.

The support housing 20 can be made of, but not limited to, metal. In this embodiment, the support housing 20 includes a base 22, a back plate 24 mounted on a top side of the base 22, two side plates 26 mounted on the top side of the base 22 and connected with left and right sides of the back plate 24, and a support plate 28 mounted with the back plate 24 and provided at a bottom side thereof with two protrusions 282 protruding downwardly. Further, the support housing 20 has two first positioning portions 29 formed on the back plate 24. In this embodiment, each first positioning portion 29 is a hole with a first section 292 and a second section 294, which is communicated with the first section 292 and has a diameter smaller than that of the first section 292.

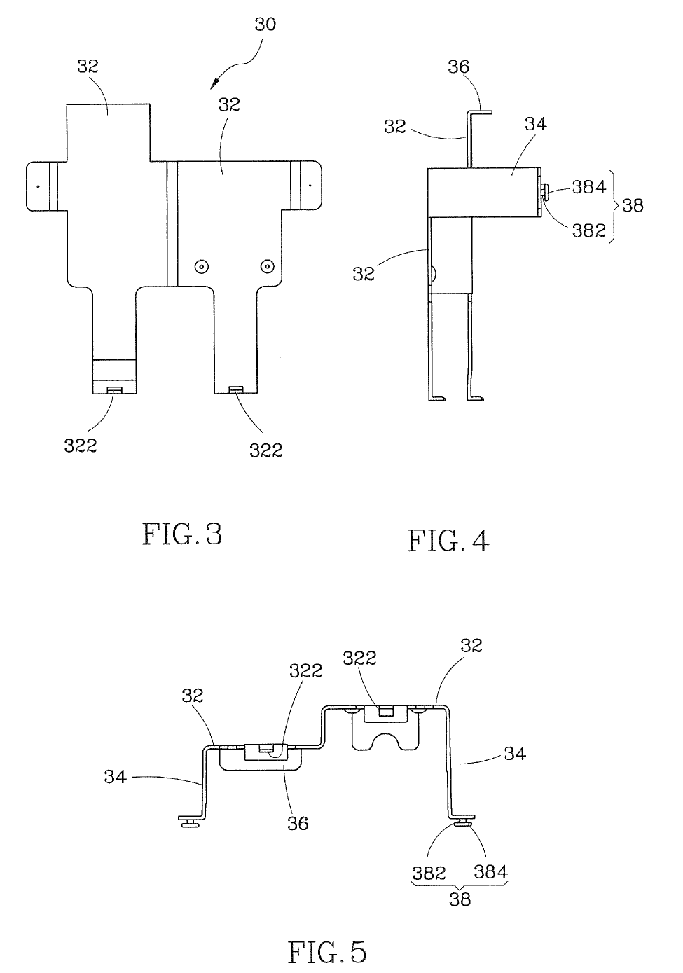

The retaining member 30 can be made of, but not limited to, metal. As shown in FIGS. 3-5, the retainer member 30 includes two retaining portions 32 connected with each other and facing the back plate 24 of the support housing 20 and respectively provided at a bottom thereof with a groove 322, two aim portions 34 respectively extending from one side of the retaining portion 32 toward the back plate 24 of the support housing 20, and two stopping portions 36 connected with tops of the retaining portions 32 and extending from the retaining portions 32 toward the back plate 24 of the support housing 20. Furthermore, the retaining member 30 has a second positioning portion 38 on a distal end of each of the arm portions 34. In this embodiment, each the second positioning portion 38 has a shaft 382, which is smaller in diameter than the first section 292 and the second section 294 of the first positioning portion 29 of the support housing 20 such that the shaft 382 can pass through the first section 292 and the second section 294 of the first positioning portion 29 of the support housing 20, and a circular block 384, which is smaller in diameter than the first section 292 of the first positioning portion 29 of the support housing 20 but larger than the second section 294 of the first positioning portion 29 of the support housing 20 such that the block 384 can pass through the first section 292 of the first positioning portion 29 of the support housing 20 but can't pass through the second section 294 of the first positioning portion 29 of the support housing 20.

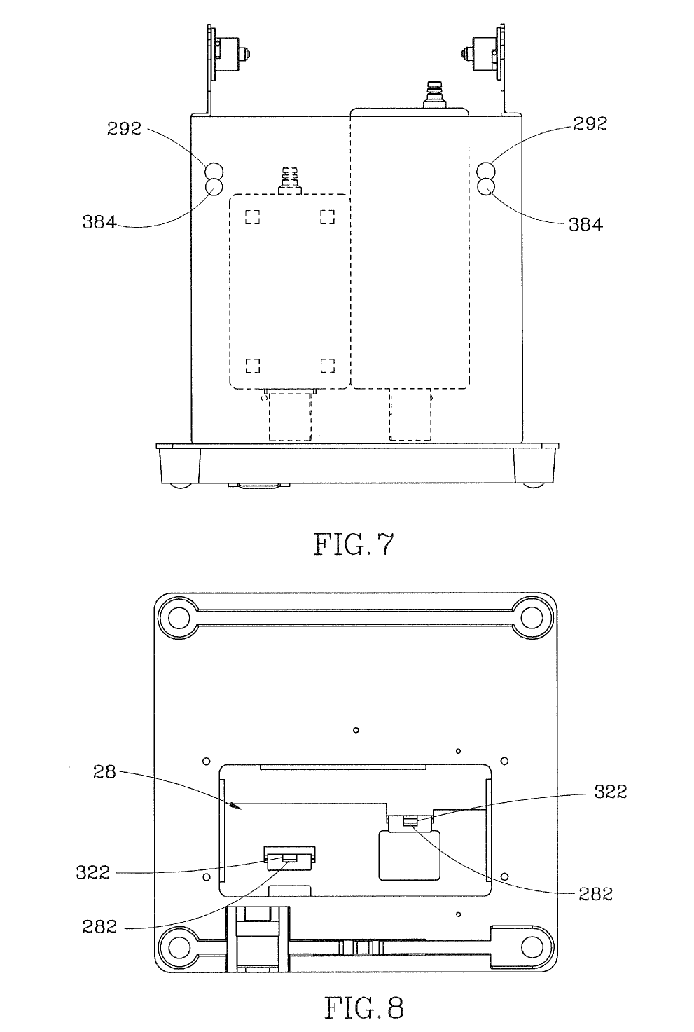

By means of above-mentioned retaining structure of the present invention, a user can use the retaining structure 10 to hold the electronic devices 40 therein, as shown in FIG. 6. In assembly, the electronic devices 40 can be firstly placed on the support plate 28, and then covered by the retaining portions 32 of the retaining member 30. Thereafter, the blocks 384 of the second positioning portions 38 of the retaining member 30 can be forced to pass through the first sections 292 of the first positioning portions 29 of the support housing 20, and then the retaining member 30 can be forcedly pulled downwardly such that the shafts 382 of the second positioning portions 38 of the retaining member 30 can be received in the second sections 294 of the first positioning portions 29 of the support housing 20. At this time, the blocks 384 can't pass through the second sections 294 of the first positioning portions 29 of the support housing 20 so as to fasten the retaining member 30 to the back plate 24 of the support housing 20, as shown in FIG. 7. In addition, the two grooves 322 of the retaining member 30 can be engaged with the two protrusions 282 of the support plate 28, as shown in FIG. 8, thereby retaining the electronic devices 40 between the support housing 20 and the retaining member 30. Furthermore, the stopping portions 36 of the retaining member 30 can stop at the tops of the electronic devices 40 to enhance the stabilization of the electronic devices 40.

On the contrary, when the user would like to depart the electronic devices 40 from the retaining structure 10, he/she can pull open the bottom of the retaining member 30 such that the grooves 322 of the retaining member 30 can be disengaged from the protrusions 282 of the support plate 28, and then force the retaining member 30 to move upwardly such that the shafts 382 of the second positioning portions 38 of the retaining member 30 can be moved away from the second sections 294 to the first section 292 of the first positioning portions 29 of the support housing 20 so that the blocks 384 of the second positioning portions 38 of the retaining member 30 can pass through the first sections 292 of the first positioning portions 29 of the support housing 20, thereby disassembling the retaining member 30 from the support housing 20. As a result, the electronic devices 40 can be exchanged and/or repaired conveniently without using any tool.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A retaining structure for holding one or more electronic devices inside a point of sale system terminal, the retaining structure comprising:
a support housing having a back plate, two side plates connected with two opposite sides of the back plate, at least two first positioning portions formed on the back plate, and a support plate mounted on the back plate and having at least one protrusion; and
a retaining member having at least two second positioning portions detachably coupled to the at least two first positioning portions of the support housing, and at least one groove engaged with the protrusion of the support plate for holding the electronic device between the support housing and the retaining member.

2. The retaining structure as claimed in claim 1, wherein each said first positioning portion of the support housing is a hole with a first section and a second section communicated with the first section and having a diameter smaller than that of the first section, and each said second positioning portion of the retaining member has a block passable through the first section of the first positioning portion of the support housing, and a shaft connected with the block and receivable in the second section of the first positioning portion of the support housing.

3. The retaining structure as claimed in claim 1, wherein the retaining member has two retaining portions connected with each other and facing the back plate of the support housing, and two arm portions extending from the retaining portions toward the back plate of the support housing; the second positioning portions are formed on free ends of the arm portions and the groove is formed on a bottom of one of the retaining portions.

4. The retaining structure as claimed in claim 3, wherein the retaining member further has two stopping portions extending from the retaining portions toward the back plate of the support housing.

5. The retaining structure as claimed in claim 1, wherein the support plate of the support housing has two said protrusions and the retaining member has two said grooves engaged with said protrusions.
